(19) United States
(12) Patent Application Publication
(10) Pub. No.: US 2014/0159182 A1
(43) Pub. Date: Jun. 12, 2014

(54) SEMICONDUCTOR DEVICE AND METHOD FOR MANUFACTURING A SEMICONDUCTOR DEVICE HAVING AN UNDULATING REFLECTIVE SURFACE OF AN ELECTRODE

(71) Applicant: THINSILLICON CORPORATION, Mountain View, CA (US)

(72) Inventors: MARK EDWARD DANTE, San Francisco, CA (US); KEVIN MICHAEL COAKLEY, Belmont, CA (US)

(73) Assignee: ThinSillicon Corporation, Mountain View, CA (US)

(21) Appl. No.: 13/707,139

(22) Filed: Dec. 6, 2012

(51) Int. Cl. H01L 31/18; H01L 31/0232

(52) U.S. Cl. CPC H01L 31/18; H01L 31/02327
USPC 257/432; 438/72

(57) ABSTRACT

A method for manufacturing a semiconductor device includes providing a substrate and a back electrode disposed between the substrate and an active semiconductor layer. The back electrode has a reflective layer that is reflective to at least one wavelength of light and includes a reflective surface having an undulating profile that includes peaks and valleys. The method includes depositing a filler layer onto the reflective layer of the back electrode. The filler layer at least partially fills one or more of the valleys of the reflective surface. The filler layer is transmissive to the at least one wavelength of light such that the at least one wavelength of light can pass through the filler layer to the reflective layer. The method includes depositing the active semiconductor layer onto the filler layer such that the filler layer and the back electrode are disposed between the substrate and the active semiconductor layer.

### BACKGROUND

The subject matter described and/or illustrated herein generally relates to semiconductor devices, such as photovoltaic devices.

Some known semiconductor devices include active semiconductor layers. The active semiconductor layers absorb incident light and convert the incident light into electric current. For example, light absorbed by the active semiconductor layers can excite electrons from atoms within the layers. The electrons are collected by conductive electrodes of the semiconductor device and flow through the electrodes to generate electric current.

The efficiency of a semiconductor device in converting incident light into electric current may depend on how much light is absorbed by the active semiconductor layers. For example, in a photovoltaic device having an NIP or PIN semiconductor junction, the efficiency of the photovoltaic device may be dependent on how much light is absorbed by the intrinsic semiconductor layer, or the “I” layer of the junction.

One manner to increase the absorption of light by an active semiconductor layer is to increase the amount of reflected light that is scattered by a back reflector (e.g., a reflective electrode) of the device. For example, the back reflector may include a reflective surface that is provided with an undulating profile that increases the amount of reflected light that is scattered by the back reflector. But, it may be difficult to deposit the active semiconductor layers on the undulating profile of the back reflector. For example, it may be difficult to grow certain materials (e.g., microcrystalline silicon (Si), zinc oxide (ZnO), and/or the like) on such undulating profiles without introducing defects in the active semiconductor layers. Such defects may lead to a relatively low open current voltage (V_{oc}) and/or a relatively low fill factor for the photovoltaic device. Some known methods for depositing active semiconductor layers on the undulating profile of a back reflector use reactive ion etching (RIE) to smooth out the undulating profile and thereby deposit the active semiconductor layers on the back reflector with less defects. But, smoothing out of the undulating profile of the back reflector at least partially defeats the purpose of the undulating profile by reducing the amount of reflected light that is scattered by the electrode, which may cause the photovoltaic device to be less efficient.

### BRIEF DESCRIPTION

In one embodiment, a method is provided for manufacturing a semiconductor device. The method includes providing a substrate and a back electrode disposed between the substrate and an active semiconductor layer. The back electrode has a reflective layer that is reflective to at least one wavelength of light. The reflective layer includes an undulating reflective surface having an undulating profile that includes peaks that protrude away from the substrate and valleys that extend into the reflective layer toward the substrate. The method also includes depositing a filler layer onto the reflective layer of the back electrode such that the active semiconductor layer can be subsequently deposited onto the filler layer. The filler layer at least partially fills one or more of the valleys of the undulating profile of the reflective surface. The filler layer is transmissive to the at least one wavelength of light such that the at least one wavelength of light can pass through the filler layer to the reflective layer of the back electrode. The method also includes depositing the active semiconductor layer onto the filler layer such that the filler layer and the back electrode are disposed between the substrate and the active semiconductor layer. The filler layer is positioned such that at least a portion of incident light passes through the active semiconductor layer into the filler layer, passes through the filler layer, is reflected by the reflective layer of the back electrode, and passes back through the filler layer to be absorbed by the active semiconductor layer.

In another embodiment, a semiconductor device includes a substrate, an active semiconductor layer, and a back electrode disposed between the substrate and the active semiconductor layer. The back electrode includes a reflective layer that is configured to reflect at least one wavelength of light. The reflective layer includes a reflective surface having an undulating profile that includes peaks that protrude away from the substrate and valleys that extend into the reflective layer toward the substrate. A filler layer is disposed between the reflective surface of the reflective layer of the back electrode and the active semiconductor layer. The filler layer at least partially fills one or more of the valleys of the undulating profile of the reflective surface. The filler layer is transmissive to the at least one wavelength of light such that the at least one wavelength of light can pass through the filler layer to the reflective layer of the back electrode. The filler layer is positioned such that at least a portion of incident light passes through the active semiconductor layer into the filler layer, passes through the filler layer, is reflected by the reflective layer of the back electrode, and passes back through the filler layer to be absorbed by the active semiconductor layer.

In another embodiment, a method is provided for manufacturing a semiconductor device. The method includes providing a substrate and a back electrode disposed between the substrate and an active semiconductor layer. The back electrode has a reflective layer that is reflective to at least one wavelength of light. The reflective layer includes an undulating reflective surface having an undulating profile that includes peaks that protrude away from the substrate and valleys that extend into the reflective layer toward the substrate. The back electrode includes a conductive light transmissive layer that is disposed above the reflective surface of the reflective layer such that the reflective layer is disposed between the substrate and the conductive light transmissive layer. The method includes depositing a filler layer onto the conductive light transmissive layer of the back electrode such that the active semiconductor layer can be subsequently deposited onto the filler layer. The filler layer at least partially fills one or more of the valleys of the undulating profile of the reflective surface. The filler layer is transmissive to the at least one wavelength of light such that the at least one wavelength of light can pass through the filler layer to the reflective layer of the back electrode. The method includes depositing the active semiconductor layer onto the filler layer such that the filler layer and the back electrode are disposed between the substrate and the active semiconductor layer. The filler layer is positioned such that at least a portion of incident light passes through the active semiconductor layer into the filler layer, passes through the filler layer into the conductive light transmissive layer, passes through the conductive light transmissive layer, is reflected by the reflective layer of the back electrode, and passes back through the conductive light transmissive layer and the filler layer to be absorbed by the active semiconductor layer.

### BRIEF DESCRIPTION OF THE DRAWINGS

FIG. 1 is a perspective view of an example embodiment of a semiconductor device.

FIG. 2 is a partial cross-sectional view of the semiconductor device shown in FIG. 1 taken along line 2-2 of FIG. 1.

FIG. 3 is a partial cross-sectional view of another embodiment of a semiconductor device.

FIG. 4 is an enlarged partial cross-sectional view of the semiconductor device shown in FIGS. 1 and 2 illustrating an embodiment of a filler layer of the semiconductor device.

FIG. 5 is a plan view of a portion of the semiconductor device shown in FIGS. 1, 2, and 4 illustrating the filler layer and an embodiment of a reflective surface of a back electrode of the semiconductor device.

FIG. 6 is a partial cross-sectional view of another embodiment of a semiconductor device.

FIG. 7 is a partial cross-sectional view of another embodiment of a semiconductor device.

FIG. 8 is a partial cross-sectional view of another embodiment of a semiconductor device.

FIG. 9 is a partial cross-sectional view of another embodiment of a semiconductor device.

FIG. 10 is a partial cross-sectional view of another embodiment of a semiconductor device.

FIG. 11 is a flowchart for an example embodiment of a method of manufacturing a semiconductor device.

FIG. 12 illustrates an exemplary back electrode of a sample filler layer device and a control sample device at various magnifications.

FIG. 13 is a graph illustrating EQE plots for a sample semiconductor device and a control semiconductor device.

FIG. 14 is a graph illustrating reflectivity data for the sample semiconductor device and for the control semiconductor device.

### DETAILED DESCRIPTION

The foregoing summary, as well as the following detailed description of certain embodiments of the subject matter set forth herein, will be better understood when read in conjunction with the appended drawings. As used herein, an element or step recited in the singular and proceeded with the word “a” or “an” should be understood as not excluding plural of said elements or steps, unless such exclusion is explicitly stated. Furthermore, references to “one embodiment” are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

In accordance with one or more embodiments described herein, semiconductor devices and methods for manufacturing semiconductor devices are provided. The semiconductor device may include a back electrode that includes a reflective layer having a reflective surface that includes an undulating profile having peaks and valleys. The undulating reflective surface may be the reflective surface of a back electrode in a photovoltaic device. A filler layer is disposed on the reflective layer of the back electrode such that the filler layer at least partially fills one or more of the valleys of the undulating profile of the reflective surface. The filler layer is transmissive to at least one wavelength of light that the reflective layer reflects. Additional layers may be disposed above the back electrode. In a photovoltaic device, for example, one or more active semiconductor layers may be disposed above the back electrode to form an NIP or PIN junction. The filler layer may increase an effective smoothness of the reflective surface of the reflective layer, which may facilitate the deposition of the active semiconductor layer(s) onto and/or above the back electrode. For example, the filler layer may ease the growth of microcrystalline silicon (Si), zinc oxide (ZnO), and/or the like onto and/or above the back electrode. The filler layer may facilitate the deposition of one or more active semiconductor layers onto and/or above the back electrode without decreasing the amount of reflected light that is scattered by the undulating profile of the reflective surface of the reflective layer of the back electrode. Moreover, the filler layer may increase the amount of reflected light that is scattered by the reflective layer of the back electrode. As the amount of scattered light is increased, the efficiency of the photovoltaic device in converting light into electric current also may increase.

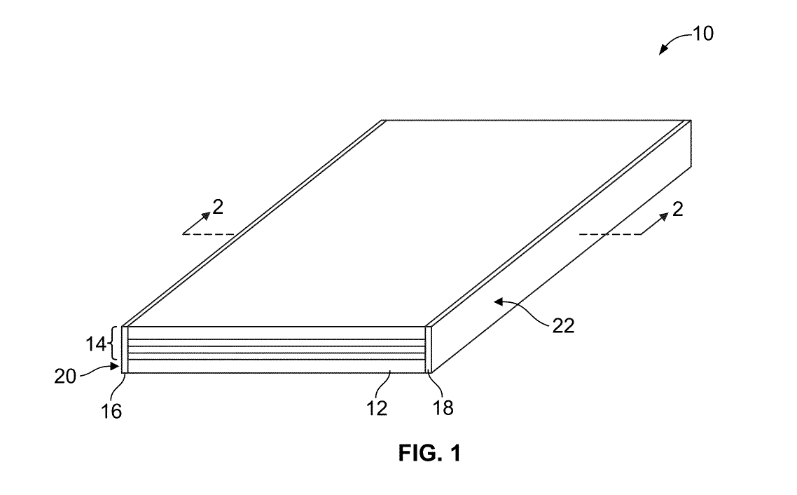

FIG. 1 is a perspective view of an example embodiment of a semiconductor device 10. In the illustrated embodiment of the semiconductor device 10, the semiconductor device 10 is a photovoltaic module that converts incident light into electric current. The semiconductor device 10 includes a substrate 12 with several layers 14 disposed above the substrate 12. By “above,” it is intended that the layers 14 are deposited onto the substrate 12 and/or onto one or more intervening layers that are deposited on the substrate 12. The semiconductor device 10 includes conductive leads 16 and 18 that are joined to, and extend along, opposite sides 20 and 22 of the semiconductor device 10.

The semiconductor device 10 receives incident light and one or more of the layers 14 convert the incident light into electric current. The layers 14 may include one or more active semiconductor junctions, such as an NIP or PIN junction that includes n-doped (“N”), p-doped (“P”), and intrinsic (“I”) semiconductor layers, and one or more conductive layers, for example electrodes. The active semiconductor junctions convert the light into electrons that are collected at, and flow through, the electrodes to thereby generate electric current. The electrodes are coupled with the leads 16 and 18 to draw the current out of the semiconductor device 10. Conductive bodies such as wires, busses, and/or the like are coupled with the leads 16 and 18 to convey the current to an electric load. While embodiments described herein refer to the semiconductor device 10 as being a photovoltaic device, alternatively the semiconductor device 10 may include a different device, such as a transistor, another solid state electronic device, and/or the like.

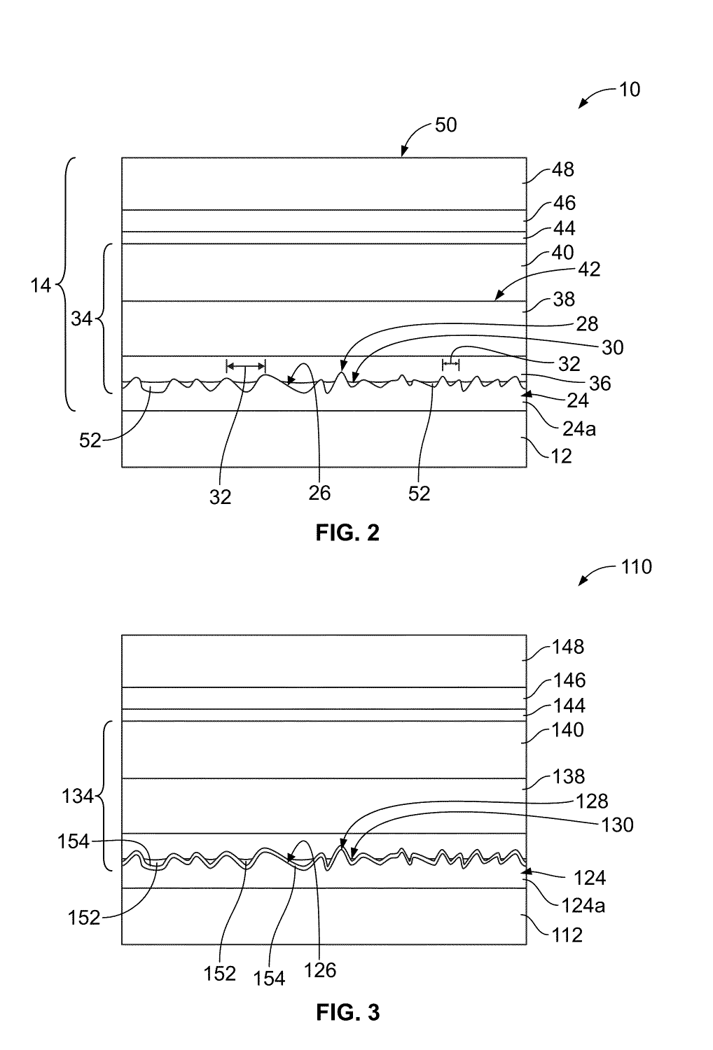

FIG. 2 is a partial cross-sectional view of the semiconductor device 10 taken along line 2-2 of FIG. 1. The leads 16 and 18 (shown in FIG. 1) are not shown in FIG. 2. Additionally, the cross-sectional view shown in FIG. 2 may not represent the cross-sectional view across the entirety of the width of the semiconductor device 10. For example, the cross-sectional view of FIG. 2 may represent a single photovoltaic cell of the semiconductor device 10 while the semiconductor device 10 includes several serially coupled photovoltaic cells disposed side-by-side along the width of the semiconductor device 10 between the leads 16 and 18.

The layers 14 of the semiconductor device 10 include a back electrode 24 that is disposed between the substrate 12 and a semiconductor layer stack 34. In the illustrated embodiment of the back electrode 24, the back electrode 24 includes a reflective layer 24a, which may be formed from an electrically conductive material, such as, but not limited to, a metal, a metal alloy, and/or the like. Examples of metal and metal alloys that may be included in the reflective layer 24a of the back electrode 24 include but are not limited to, silver (Ag), indium tin oxide (ITO), and/or the like. The reflective layer 24a of the back electrode 24 is configured to reflect at least one wavelength of light, as will be described below.

The reflective layer 24a of the back electrode 24 includes a reflective surface 26 that has an undulating profile. For example, the reflective surface 26 of the reflective layer 24a may be a three dimensional surface having features that extend in three mutually orthogonal directions. The reflective surface 26 shown in FIG. 2 includes peaks 28 that extend away from the substrate 12 and valleys 30 that extend toward the substrate 12. The peaks 28 and/or valleys 30 also may extend in directions that are perpendicular to the plane of FIG. 2. For example, the peaks 28 may have approximate convex pyramidal and/or conical shapes that extend (e.g., protrude) away from the back electrode 24 and the valleys 30 may have approximate concave pyramidal and/or conical shapes that extend into the bulk of the back electrode 24. The peaks 28 and/or the valleys 30 of the reflective surface 26 may be arranged in a non-regular pattern. In a non-regular pattern, a pitch dimension 32 between common points (e.g., summits) of adjacent (e.g., neighboring) peaks 28 and/or valleys 30 may significantly vary among the peaks 28 and/or valley 30. By way of example only, the pitch dimension 32 may vary by at least 10%, 15%, 20%, 25%, 30%, 35%, 40%, 45%, and/or 50% among the peaks 28 and/or valleys 30. Alternatively, in a regular pattern, the pitch dimension 32 may be relatively constant, such as, but not limited to, a pitch dimension 32 that does not vary by more than 10%, 15%, 20%, 25%, 30%, 35%, 40%, 45%, and/or 50% among the peaks 28 and/or valleys 30.

A semiconductor layer stack 34 is disposed between the back electrode 24 and one or more other layers (e.g., the layers 44, 46, and 48 described below) of the semiconductor device 10. The semiconductor layer stack 34 includes an NIP and/or PIN junction each formed from three semiconductor layers 36, 38, and 40 in the illustrated embodiment. Alternatively, the semiconductor layer stack 34 may include a different number of layers and/or additional semiconductor layer stacks 34. For example, the semiconductor layer stack 34 may include two or more junctions disposed above each other. In the illustrated embodiment of the semiconductor stack 34, the semiconductor layer stack 34 includes a middle semiconductor layer 38 disposed between outer semiconductor layers 36 and 40. The middle semiconductor layer 38 may be formed from and/or include any material, such as, but not limited to, microcrystalline Si, undoped ZnO, undoped Si (such as, but not limited to, intrinsic Si and/or the like), and/or the like. The outer semiconductor layers 36 and/or 40 may each be formed from and/or include any material, such as, but not limited to, microcrystalline Si, doped ZnO, doped Si, and/or the like. The outer semiconductor layers 36 and 40 may be doped with oppositely charged dopants. For example, the outer semiconductor layer 36 may be doped with an n-type dopant, such as, but not limited to, phosphorus (P) and/or the like, while the outer semiconductor layer 40 may be doped with a p-type dopant, such as, but not limited to, boron (B) and/or the like, to form an NIP junction. Alternatively, the outer semiconductor layer 36 may be doped with a p-type dopant and the outer semiconductor layer 40 may be doped with an n-type dopant to form a PIN junction.

The outer semiconductor layer 40 may be deposited directly on a surface 42 of the middle semiconductor layer 38 such that the layer 40 abuts the surface 42 of the layer 38, or may be deposited on one or more intervening layers (not shown) that are deposited directly on the surface 42. A light transmissive electrode 44 is disposed above the semiconductor layer stack 34. The light transmissive electrode 44 may be formed from an electrically conductive material, such as, but not limited to, a metal, a metal alloy, and/or the like. Examples of metal and metal alloys that may be included in the light transmissive electrode 44 include but are not limited to, Ag, ITO, and/or the like. In the illustrated embodiment of the semiconductor device 10, the light transmissive electrode 44 is at least partially transmissive to light and permits at least some wavelengths of light to pass through the light transmissive electrode 44. Although only one is shown, the light transmissive electrode 44 may include any number of layers.

An adhesive layer 46 may be disposed between the light transmissive electrode 44 and a cover layer 48. The adhesive layer 46 affixes the cover layer 48 to the light transmissive electrode 44. The cover layer 48 may include a glass sheet and/or other component that protects the underlying layers 14 from damage.

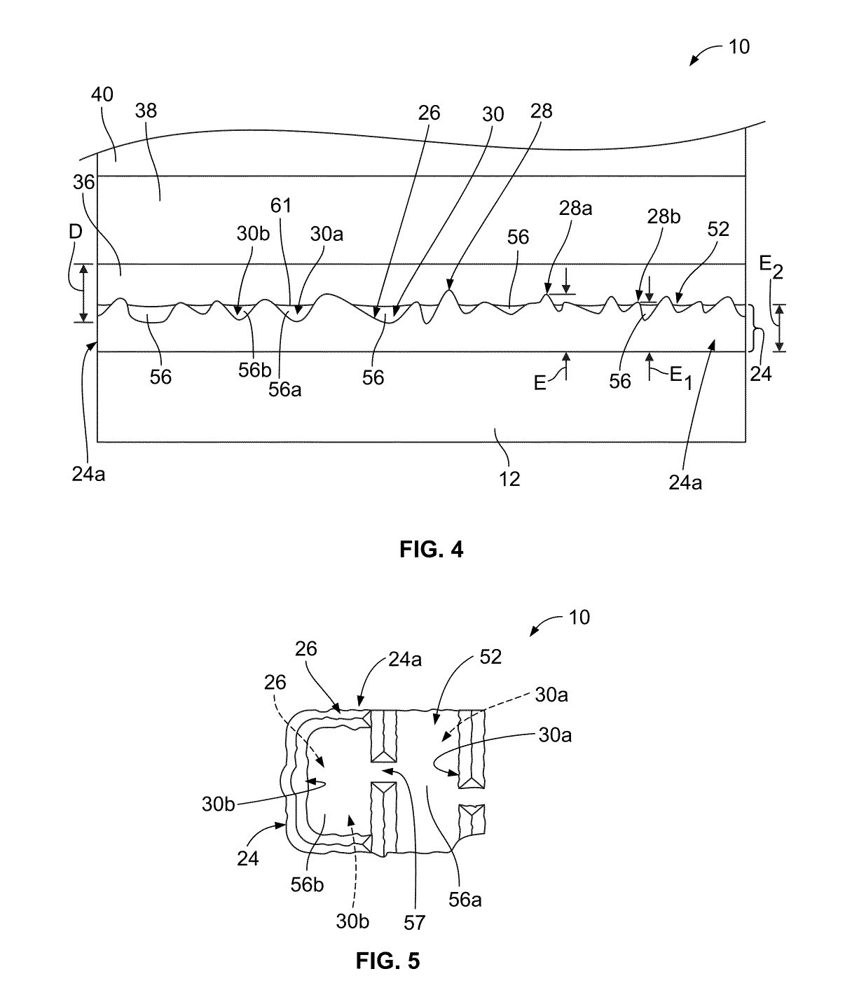

The semiconductor device 10 includes a filler layer 52 that is disposed between the reflective surface 26 of the reflective layer 24a of the back electrode 24 and the semiconductor layer stack 34. The filler layer 52 at least partially fills one or more of the valleys 30 of the undulating profile of the reflective surface 26. In the illustrated embodiment of the back electrode 24, the filler layer 52 is deposited directly onto the reflective surface 26 of the reflective layer 24a such that the filler layer 52 abuts the reflective surface 26 of the reflective layer 24a. The filler layer 52 is configured to be transmissive to one or more wavelengths of light that the reflective layer 24a is configured to reflect such that the one or more wavelengths of light can pass through the filler layer 52 to the reflective layer 24a of the back electrode 24. The filler layer 52 will be described and illustrated in more detail below with respect to FIG. 4. Although shown as having only the reflective layer 24a, the back electrode 24 may include a different number of layers

In operation, incident light is received through a light receiving surface 50 of the semiconductor device 10 that is opposite of the substrate 12. The light passes through the surface 50, through the cover layer 48, through the adhesive layer 46, and through the light transmissive electrode 44 into the semiconductor layer stack 34. Some of the light is absorbed by the semiconductor stack 34 as the light passes through the semiconductor stack 34. Another portion of the light passes through the semiconductor stack 34 and is reflected and/or scattered by the back electrode 24. Specifically, the filler layer 52 is positioned such that at least a portion of incident light passes through the semiconductor layer stack 34 into the filler layer 52, and passes through the filler layer 52 to the reflective surface 26 of the reflective layer 24a of the back electrode 24. The reflective layer 24a is configured such that the reflective surface 26 is configured to reflect one or more wavelengths of the incident light that passes through the semiconductor layer stack 24 and the filler layer 52. Light that is reflected by the reflective surface 26 of the reflective layer 24a passes back through the filler layer 52 and at least some of the reflected light is absorbed by the semiconductor layer stack 34. Light absorbed by the semiconductor stack 34 is used to generate electric current.

The undulating reflective surface 26 of the reflective layer 24a of the back electrode 24 may increase the amount of reflected light that is scattered by the back electrode 24, which may increase the amount of light that is absorbed and used to generate electric current by the semiconductor layer stack 34. Increasing the amount of light that is absorbed by the semiconductor layer stack 34 may increase the amount of electric current generated by the semiconductor device 10 without significantly increasing the thickness of the semiconductor layer stack 34.

In some alternative embodiments, instead of receiving light through the light receiving surface 50, the semiconductor device 10 may receive light through the substrate 12 with the back electrode 24 being at least partially transmissive to light and the light transmissive electrode 44 reflecting light. In such alternative embodiments, the light transmissive electrode 44 includes an undulating surface (not shown) that is substantially similar to the undulating surface 26 of the reflective layer 24a of the back electrode 24, which may not include an undulating surface.

In some embodiments, the back electrode 24 includes a conductive light transmissive layer, which is not included in the semiconductor device 10 of FIGS. 1 and 2. For example, FIG. 3 is a partial cross-sectional view of another embodiment of a semiconductor device 110. The cross-sectional view shown in FIG. 3 may not represent the cross-sectional view across the entirety of the width of the semiconductor device 110.

The semiconductor device 110 includes a substrate 112, a semiconductor layer stack 134, and a back electrode 124 that is disposed between the substrate 112 and the semiconductor layer stack 134. The semiconductor layer stack 134 includes an NIP and/or PIN junction formed from three semiconductor layers 136, 138, and 140. Alternatively, the semiconductor layer stack 134 may include a different number of layers and/or additional semiconductor layer stacks 134.

A light transmissive electrode 144 is disposed above the semiconductor layer stack 134. The light transmissive electrode 144 may be formed from an electrically conductive material, such as, but not limited to, a metal, a metal alloy, and/or the like. In the illustrated embodiment of the semiconductor device 110, the light transmissive electrode 144 is at least partially transmissive to light and permits at least some wavelengths of light to pass through the light transmissive electrode 144. An adhesive layer 146 may be disposed between the light transmissive electrode 144 and a cover layer 148.

The back electrode 124 includes a reflective layer 124a, which may be formed from an electrically conductive material, such as, but not limited to, a metal, a metal alloy, and/or the like. One example of a metal that may be included in the reflective layer 124a of the back electrode 124 is silver (Ag). The reflective layer 124a of the back electrode 124 is configured to reflect at least one wavelength of light. The reflective layer 124a of the back electrode 124 includes a reflective surface 126 having an undulating profile that includes peaks 128 and valleys 130.

The back electrode 124 includes a conductive light transmissive layer 154. In the illustrated embodiment of the back electrode 124, the conductive light transmissive layer 154 is deposited directly on the reflective layer 124a such that the layer 154 abuts the reflective surface 126 of the reflective layer 124a. The conductive light transmissive layer 154 includes and/or is formed from one or more materials that is electrically conductive and that allows at least some wavelengths of light to pass through the layer 154. For example, the conductive light transmissive layer 154 may be configured to be transmissive to one or more wavelengths of light that the reflective layer 124a is configured to reflect. By way of example only, the conductive light transmissive layer 154 may be a conductive layer that includes and/or is formed from indium tin oxide (ITO), aluminum doped zinc oxide (Al:ZnO), boron doped zinc oxide (B:ZnO), gallium doped zinc oxide (Ga:ZnO), another type of zinc oxide (ZnO) that conducts electric current, and/or the like.

A filler layer 152 of the semiconductor device 110 is disposed above the reflective surface 126 of the reflective layer 124a such that the filler layer 152 and the back electrode 124 are disposed between the substrate 112 and the semiconductor layer stack 134. The filler layer 152 at least partially fills one or more of the valleys 130 of the reflective surface 126. In the illustrated embodiment of the back electrode 124, the filler layer 152 is deposited directly on the conductive light transmissive layer 154 such that the filler layer 152 abuts the layer 154. The filler layer 152 is configured to be transmissive to one or more wavelengths of light that the reflective layer 124a is configured to reflect. The back electrode 124 may include any number of layers.

In operation, incident light passes through the through the cover layer 148, through the adhesive layer 146, and through the light transmissive electrode 144 into the semiconductor layer stack 134. Some of the light is absorbed by the semiconductor stack 134 as the light passes through the semiconductor stack 134. Another portion of the light passes through the semiconductor stack 134 and is reflected and/or scattered by the back electrode 124. Specifically, the filler layer 152 is positioned such that at least a portion of incident light passes through the semiconductor layer stack 134 into the filler layer 52, passes through the filler layer 52 into the conductive light transmissive layer 154, and passed through the conductive light transmissive layer 154 to the reflective surface 126 of the reflective layer 124a of the back electrode 124. The reflective layer 124a is configured such that the reflective surface 126 is configured to reflect one or more wavelengths of the incident light that passes through the semiconductor layer stack 124, the filler layer 152, and the conductive light transmissive layer 154. Light that is reflected by the reflective surface 126 of the reflective layer 124a passes back through the conductive light transmissive layer 154 and the filler layer 152 and at least some of the reflected light is absorbed by the semiconductor layer stack 34.

Referring again to the semiconductor device 10, FIG. 4 is an enlarged partial cross-sectional view of the semiconductor device 10 illustrating the illustrated embodiment of the filler layer 52. The cross-sectional view shown in FIG. 4 may not represent the cross-sectional view across the entirety of the width of the semiconductor device 10. For example, the cross-sectional view of FIG. 4 may represent a single photovoltaic cell of the semiconductor device 10 while the semiconductor device 10 includes several serially coupled photovoltaic cells disposed side-by-side along the width of the semiconductor device 10 between the leads 16 and 18 (shown in FIG. 1) of the semiconductor device 10.

The filler layer 52 at least partially fills at least some of the valleys 30 of the reflective surface 26 of the reflective layer 24a. As can be seen in FIG. 4, the illustrated embodiment of the filler layer 52 only partially fills the valleys 30, such that the peaks 28 are exposed through the filler layer 52. Specifically, the filler layer 52 includes a plurality of filler bodies 56 that extend within corresponding valleys 30 of the reflective surface 26. Each filler body 56 only fills a portion of the depth D of the corresponding valley 30. Accordingly, the peaks 28 are exposed above the filler bodies 56. Each filler body 56 may or may not be connected to one or more neighboring filler bodies 56 that extend within one or more adjacent valleys 30. For example, FIG. 5 is a plan view of a portion of the semiconductor device 10. The layers 36, 38, 40, 44, 46, and 48 have been removed from the semiconductor device 10 in FIG. 5 to illustrate the filler layer 52 and the reflective surface 26 of the reflective layer 24a of the back electrode 24. Referring now to FIGS. 4 and 5, the filler body 56a that extends within the valley 30a may be connected to the filler body 56b that extends within the adjacent valley 30b, for example via a channel 57 of the reflective surface 26 that interconnects the valleys 30a and 30b. Referring again solely to FIG. 4, in some embodiments, none of the valleys 30 is connected to an adjacent valley 30 such that each of the filler bodies 56 is discrete from each other filler body 56. 20. For example, the filler layer 52 may be a non-continuous layer having separate and discrete filler bodies 56 that are separated from each other by the peaks 30 of the reflective surface 26. In some other embodiments, each of the valleys 30 is connected to at least one adjacent valley 30 and each filler body 56 is connected to at least one neighboring filler body 56.

Although all of the peaks 28 are shown in FIG. 4 as being exposed through the filler layer 52, any number of the peaks 28 may be exposed through the filler layer 52. Specifically, in some alternative embodiments, all of the peaks 28 are covered by the filler layer 52. Moreover, in some alternative embodiments, some of the peaks 28 are exposed through the filler layer 52, while other peaks 28 are not exposed through the filler layer 52. For example, different peaks 28 of the reflective surface 26 may have different elevations (e.g., the peak 28a has an elevation E that is higher than the elevation E₁ of the peak 28b), and the thickness of the filler layer 52 may be selected to provide the filler layer 52 with an elevation E₂ that covers some of the peaks 28 but does not cover other peaks 28. In other embodiments, all of the peaks 28 have approximately the same elevation, and the thickness of the filler layer 52 may be selected such that the filler layer 52 has an elevation E₂ that covers all of the peaks 28 or has an elevation E₂ that covers none of the peaks 28. With regard to the “thickness” of the filler layer 52, it should be understood that different valleys 30 of the reflective surface 26 may have different depths D or all of the valleys 30 may have approximately the same depth D. In embodiments where different valleys 30 have different depths D, the elevation E₂ of the filler layer 52 may be approximately constant along the length and width of the reflective surface 26 while the thickness of the filler layer 52 will vary along the length and width of the reflective surface 26.

The filler layer 52 may be formed from and/or include any material that enables the filler layer 52 to function as described and/or illustrated herein. The filler layer 52 may be formed from one or more different materials than the back electrode 24. Examples of materials that the filler layer 52 may include and/or be formed from include, but are not limited to, titanium dioxide (TiO₂), titanium oxide (TiO), titanium butoxide (Ti(OBu)₄), a conductive polymer, zinc oxide (ZnO), TiOₓ, doped zinc oxide (AZO), and/or the like. Examples of conductive polymers include, but are not limited to, poly(3,4-ethylenedioxythiophene) (PEDOT), Poly(3,4-ethylenedioxythiophene) poly(styrenesulfonate) (PEDOT:PSS), and/or the like. In some embodiments, the filler layer 52 is deposited above the reflective layer 24a as a fluid solution. For example, the filler layer 52 may be disposed above the reflective layer 24a as a sol gel solution. The materials included within and/or used to form the filler layer 52 may be selected to configure the filler layer 52 to be transmissive to wavelengths of light that are reflected by the reflective layer 24a.

The filler layer 52 may increase an effective smoothness of the reflective surface 26 of the reflective layer 24a. For example, in the embodiment of the semiconductor device 10, the semiconductor layer 36 is deposited directly on a deposition surface defined by the filler layer 52 and the exposed peaks 30 of the reflective surface 26. The filler layer 52 partially fills the valleys 30. Accordingly, the deposition surface on which the semiconductor layer 36 is directly deposited is smoother than the reflective surface 26 alone. Specifically, the filler bodies 56 reduce the depth of the valleys 30 such that the undulations of the deposition surface are shallower than the undulations of the reflective surface 26 alone, thereby increasing the effective smoothness of the reflective surface 26. For example, the effective smoothness of the reflective surface 26 may be measured by measuring, at various points along the deposition surface, the distance between the tip (e.g., the point of greatest elevation) of a peak 28 and a surface 61 (which defines a portion of the deposition surface) of the filler body 56 that corresponds to the peak 28. Increasing the effective smoothness of the reflective surface 26 may facilitate the deposition of a semiconductor layer on the back electrode 24. For example, the increased smoothness of the reflective surface 26 may ease the growth of microcrystalline silicon (Si), zinc oxide (ZnO), and/or the like on the back electrode 24. Accordingly, the filler layer 52 may make it easier to deposit a semiconductor layer on the back electrode 24. The filler layer 52 may increase the effective smoothness of the reflective surface 26 of the reflective layer 24a without decreasing the amount of reflected light that is scattered by the undulating profile of the reflective surface 26 of the reflective layer 24a. The filler layer 52 may thereby facilitate the deposition of a semiconductor layer on the back electrode 24 without decreasing the amount of reflected light that is scattered by the reflective surface 26.

In some embodiments, the filler layer 52 has an elevation E₂ that completely fills one or more valleys 30 but does not cover one or more peaks 28 that correspond to the valley(s) 30 completely filled. Moreover, and as described above, the filler layer 52 may be provided with an elevation E₂ that covers some or all of the peaks 28. The amount each valley 30 is filled by the filler layer 52, whether any peaks 28 are covered by the filler layer 52, the number of peaks 28 that are covered by the filler layer 52, the number of peaks 28 that are exposed through the filler layer 52, the amount of each peak 28 that is exposed and/or covered, the materials of the filler layer 52, the elevation E₂ of the filler layer 52, and/or the like may be selected to increase the effective smoothness of the reflective surface 26 by any amount. Moreover, the amount each valley 30 is filled by the filler layer 52, whether any peaks 28 are covered by the filler layer 52, the number of peaks 28 that are covered by the filler layer 52, the number of peaks 28 that are exposed through the filler layer 52, the amount of each peak 28 that is exposed and/or covered, the materials of the filler layer 52, the elevation E₂ of the filler layer 52, and/or the like may be selected to prevent a reduction in the amount of reflected light that is scattered by the reflective surface 26.

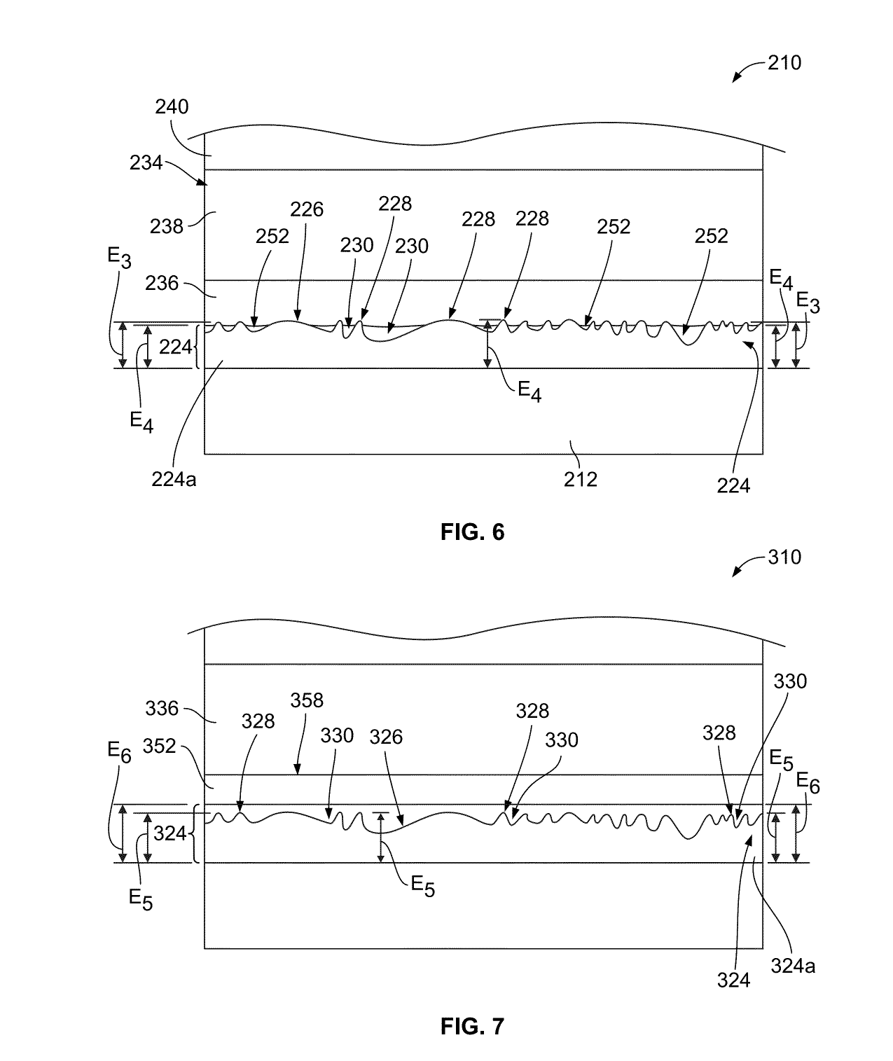

As described above, in some embodiments, all of the peaks 28 have approximately the same elevation. FIG. 6 is a partial cross-sectional view of another embodiment of a semiconductor device 210 illustrating a reflective layer 224a having an undulating reflective surface 226 that includes peaks 228 of approximately the same elevation E₃. The cross-sectional view shown in FIG. 6 may not represent the cross-sectional view across the entirety of the width of the semiconductor device 210.

The semiconductor device 210 includes a substrate 212, a semiconductor layer stack 234, and a back electrode 224 that is disposed between the substrate 212 and the semiconductor layer stack 234. The semiconductor layer stack 234 includes one or more NIP and/or PIN junctions formed from two or more semiconductor layers 236, 238, and/or 240 and/or from additional semiconductor layer stacks 234. The semiconductor device 210 may include a light transmissive electrode (not shown), an adhesive layer (not shown), and/or a cover layer (not shown) disposed above the semiconductor layer stack 234.

The back electrode 224 includes the reflective layer 224a, which is configured to reflect at least one wavelength of light. The reflective layer 224a of the back electrode 224 includes the reflective surface 226 having an undulating profile that includes the peaks 228 and valleys 230. As can be seen in FIG. 6, each of the peaks 228 has approximately the same elevation E₃.

A filler layer 252 of the semiconductor device 210 is disposed between the reflective surface 226 of the reflective layer 224a and the semiconductor layer stack 234. The filler layer 252 at least partially fills the at least some of the valleys 230 of the reflective surface 226. As described above with respect to the filler layer 52 (FIGS. 2 and 4), the thickness of the filler layer 252 may be selected such that the filler layer 252 has an elevation E₄ that covers all of the peaks 228 or has an elevation E₄ that covers none of the peaks 228. In the illustrated embodiment of the filler layer 252, the filler layer 252 is provided with a thickness such that the elevation E₄ of the filler layer 252 does not cover any of the peaks 228. In other words, all of the peaks 228 are exposed through the filler layer 252.

The filler layer 252 partially fills the valleys 230 such that the filler layer 52 and the exposed peaks 230 of the reflective surface 226 define a deposition surface on which the semiconductor layer 236 is directly deposited. The deposition surface defined by the filler layer 252 and the exposed peaks 228 of the reflective surface 226 is smoother than the reflective surface 226 alone. Accordingly, the addition of the filler layer 252 increases the effective smoothness of the reflective surface 226 for deposition of the semiconductor layer 236.

FIG. 7 is a partial cross-sectional view of another embodiment of a semiconductor device 310 illustrating another reflective layer 324a having an undulating reflective surface 326 that includes peaks 328 of approximately the same elevation E₅. Specifically, the reflective surface 326 has an undulating profile that includes the peaks 328 and valleys 330. As can be seen in FIG. 7, the elevation E₅ of each of the peaks 328 is approximately the same.

The semiconductor device 310 includes a back electrode 324, which includes the reflective layer 324a. A filler layer 352 of the semiconductor device 310 is disposed above the reflective surface 326 of the reflective layer 324a of the back electrode 324. In the illustrated embodiment of FIG. 7, the filler layer 352 is provided with a thickness such that the filler layer 352 has an elevation E₆ that covers all of the peaks 328. Specifically, the elevation E₆ of the filler layer 352 is greater than the elevation E₅ of the peaks 328 such that the filler layer 352 covers the peaks 328, as is shown in FIG. 7. In other words, none of the peaks 328 are exposed through the filler layer 352.

In the embodiment of FIG. 7, the filler layer 352 includes a surface 358 that defines a deposition surface on which a semiconductor layer 336 of the semiconductor device 310 is directly deposited. The surface 358 of the filler layer 352 is substantially smoother than the reflective surface 326 of the reflective layer 324a, such that the addition of the filler layer 352 increases the effective smoothness of the reflective surface 326 for deposition of the semiconductor layer 336.

The cross-sectional view shown in FIG. 7 may not represent the cross-sectional view across the entirety of the width of the semiconductor device 310.

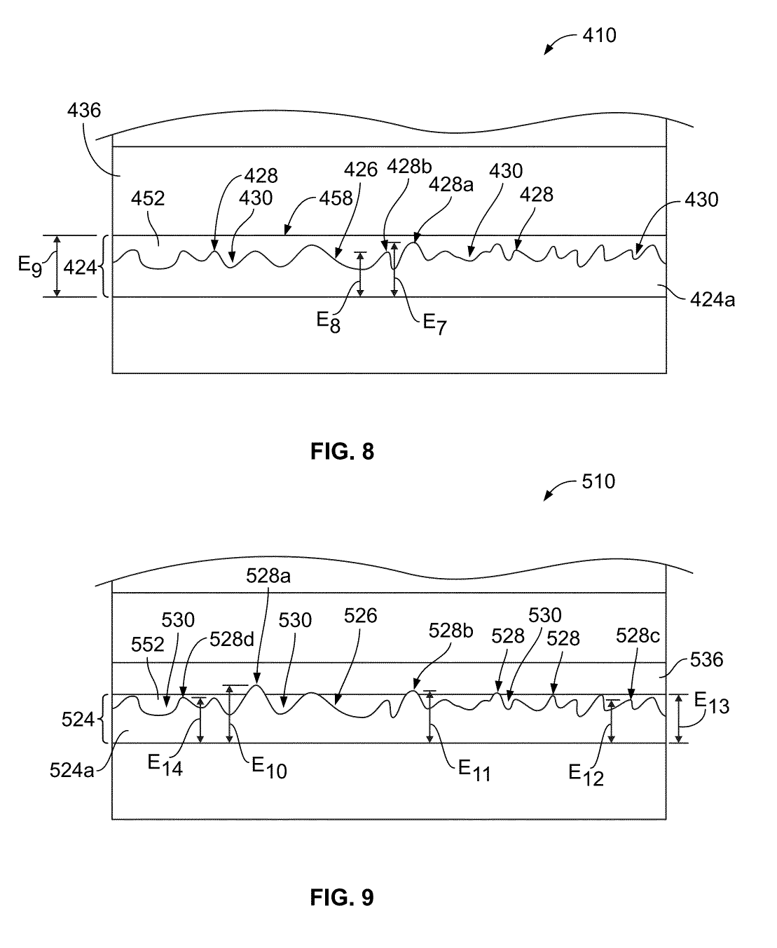

Referring again to the semiconductor device 10 (shown in FIGS. 1, 2, 4, and 5), as described above, different peaks 28 of the reflective surface 26 may have different elevations than each other. FIG. 8 is a partial cross-sectional view of another embodiment of a semiconductor device 410 illustrating another reflective layer 424a having an undulating reflective surface 426 that includes at least two peaks 428 having different elevations than each other. Specifically, the reflective surface 426 has an undulating profile that includes the peaks 428 and valleys 430. As can be seen in FIG. 8, some peaks 428 have different elevations than at least some other peaks 428. For example, the peak 428a has an elevation E₇ that is higher than the elevation E₈ of the peak 428b.

The semiconductor device 410 includes a back electrode 424, which includes the reflective layer 424a. A filler layer 452 of the semiconductor device 410 is disposed above the reflective surface 426 of the reflective layer 424a of the back electrode 424. The filler layer 452 has an elevation E₉ that covers all of the peaks 428. For example, as can be seen in FIG. 8, the elevation E₉ of the filler layer 452 is greater than the elevations E₇ and E₈ of the peaks 428a and 428b, respectively, such that the filler layer 452 covers the peaks 428a and 428h.

The filler layer 452 includes a surface 458 that defines a deposition surface on which a semiconductor layer 436 of the semiconductor device 410 is directly deposited. The surface 458 of the filler layer 452 is substantially smoother than the reflective surface 426 of the reflective layer 424a. Accordingly, the addition of the filler layer 452 increases an effective smoothness of the reflective surface 426 for deposition of the semiconductor layer 436.

The cross-sectional view shown in FIG. 8 may not represent the cross-sectional view across the entirety of the width of the semiconductor device 410.

FIG. 9 is a partial cross-sectional view of another embodiment of a semiconductor device 510 illustrating another reflective layer 524a having an undulating reflective surface 526 that includes at least two peaks 528 having different elevations than each other. The cross-sectional view shown in FIG. 9 may not represent the cross-sectional view across the entirety of the width of the semiconductor device 510. The reflective surface 526 has an undulating profile that includes the peaks 528 and valleys 530. Some peaks 528 have different elevations than at least some other peaks 528. For example, the peak 528a has an elevation E₁₀ that is higher than the elevations E₁₁ and E₁₂ of the peaks 528b and 528c, respectively. As can be seen in FIG. 9, the elevation E₁₁ of the peak 528b is higher than the elevation E₁₂ of the peak 528c.

The semiconductor device 510 includes a back electrode 524, which includes the reflective layer 524a. A filler layer 552 of the semiconductor device 510 is disposed above the reflective surface 526 of the reflective layer 524a. The filler layer 552 has an elevation E₁₃ that covers some of the peaks 528 but does not cover other peaks 528. For example, the elevation E₁₃ of the filler layer 552 is less than the elevations E₁₀ and E₁₁ of the peaks 528a and 528b, respectively, while the elevation E₁₃ of the filler layer 552 is greater than the elevations E₁₂ and E₁₄ of the peaks 528c and 528d, respectively. Accordingly, the filler layer 552 covers the peaks 528c and 528d. The peaks 528a and 528b are not covered by the filler layer 552 such that the peaks 528a and 528b are exposed through the filler layer 552.

A surface 558 of the filler layer 552 and any exposed peaks 528 (e.g., the peaks 528a and 528b) of the reflective surface 526 define a deposition surface on which a semiconductor layer 536 of the semiconductor device 510 is directly deposited. The deposition surface defined by the filler layer 552 and the exposed peaks 528 of the reflective surface 526 is smoother than the reflective surface 526 alone. The addition of the filler layer 552 therefore increases the effective smoothness of the reflective surface 526 for deposition of the semiconductor layer 536 thereon.

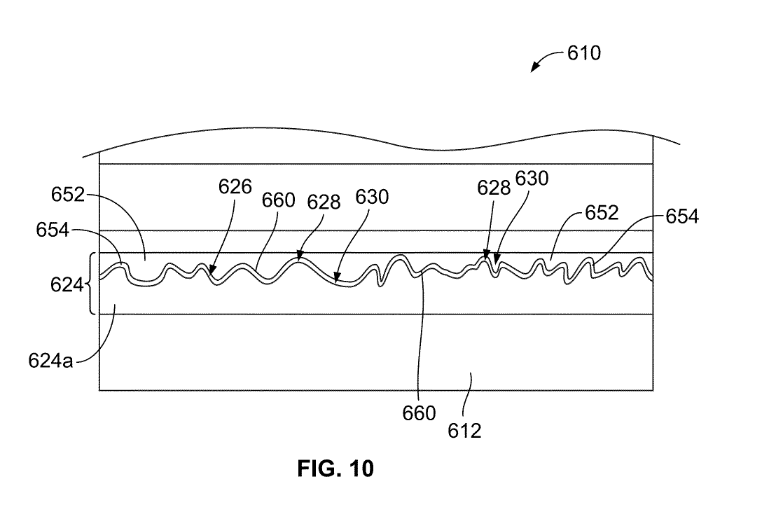

FIG. 10 is a partial cross-sectional view of another embodiment of a semiconductor device 610. The semiconductor device 610 includes a substrate 612 and a back electrode 624 disposed above the substrate 612. The back electrode 624 includes a reflective layer 624a. The reflective layer 624a of the back electrode 624 includes a reflective surface 626 having an undulating profile that includes peaks 628 and valleys 630.

The back electrode 624 includes a conductive light transmissive layer 654 that is deposited directly on the reflective layer 624a. A filler layer 652 of the semiconductor device 610 is disposed above the reflective surface 626 of the reflective layer 624a. In the illustrated embodiment of the back electrode 624, the filler layer 652 is deposited directly on the conductive light transmissive layer 654 such that the filler layer 652 abuts the layer 654 at an interface 660. The value of the index of refraction of the filler layer 652 is different than the value of the index of refraction of the conductive light transmissive layer 654.

The filler layer 652 may increase the amount of reflected light that is scattered by the reflective layer 624a of the back electrode 624. For example, the different indexes of refraction of the layers 652 and 654 may increase the amount of reflected light that is scattered by the reflective layer 624a. Specifically, as light passes through the filler layer 652 and the conductive light transmissive layer 654, the different indexes of refraction of the layers cause the light to refract and change direction at the interface 660 between the layers 652 and 654. The change of direction at the interface 660 increases the number of directions that different light rays are reflected, thereby increasing the amount of reflected light that is scattered by the reflective layer 624a relative to the amount of light scattered by the reflective layer 624a in the absence of the filler layer 652. The value of the index of refraction of the filler layer 652, the value of the index of refraction of the conductive light transmissive layer 654, the value of the difference between the indexes of refraction of the layers 652 and 654, and/or the like may be selected to increase the amount of reflected light that is scattered by the reflective layer 624a by any amount. Moreover, the value of the index of refraction of the filler layer 652, the value of the index of refraction of the conductive light transmissive layer 654, the value of the difference between the indexes of refraction of the layers 652 and 654, and/or the like may be selected to provide the reflective layer 624a with a predetermined amount of light scattering.

The cross-sectional view shown in FIG. 10 may not represent the cross-sectional view across the entirety of the width of the semiconductor device 610.

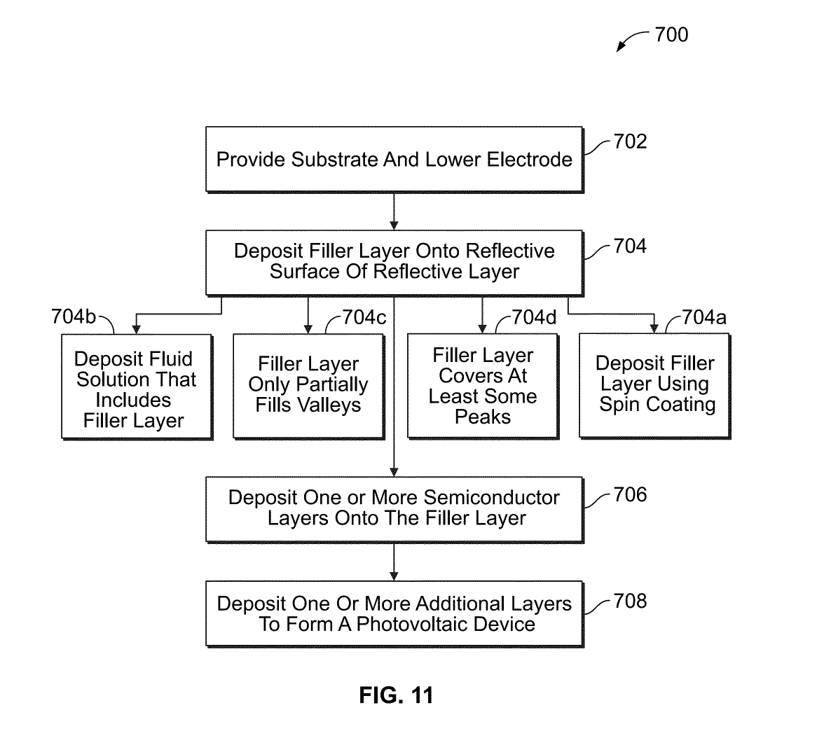

FIG. 11 is a flowchart for an example embodiment of a method 700 of manufacturing a semiconductor device. For example, the method 700 may be used to manufacture any of the semiconductor devices 10, 110, 210, 310, 410, 510, and 610, which are shown in FIGS. 2, 4, 5, 3, 6, 7, 8, 9, and 10, respectively.

At 702, the method 700 includes providing a substrate (e.g., the substrate 12 shown in FIGS. 1, 2, and 4) and a back electrode (e.g., the back electrode 24 shown in FIGS. 2, 4 and 5) disposed between the substrate and one or more active semiconductor layers (e.g., the semiconductor stack 34 shown in FIGS. 2 and 4) above the substrate. The back electrode has a reflective layer (e.g., the reflective layer 24a shown in FIGS. 2, 4, and 5) that is reflective to at least one wavelength of light. The reflective layer includes a reflective surface (e.g., the reflective surface 26 shown in FIGS. 2, 4, and 5) having an undulating profile that includes peaks and valleys (e.g., the peaks 28 and valleys 30 shown in FIGS. 2, 4, and 5).

At 704, the method 700 includes depositing a filler layer (e.g., the filler layer 52 shown in FIGS. 2, 4, and 5) onto the reflective layer of the back electrode such that the active semiconductor layer can be subsequently deposited onto the filler layer. The filler layer at least partially fills one or more of the valleys of the undulating profile of the reflective surface. The filler layer is transmissive to the at least one wavelength of light such that the at least one wavelength of light can pass through the filler layer to the reflective layer of the back electrode. The filler layer may be deposited at 704 above the reflective surface of the reflective layer using any suitable method, process, means, and/or the like, such as, but not limited to, spin coating (i.e., spin casting), doctor blading, and/or the like. For example, in some embodiments, depositing the filler layer at 704 includes depositing, at 704a, the filler layer using spin coating.

The filler layer may be deposited at 704 in any form. For example, in some embodiments, depositing at 704 the filler layer of the back electrode above the reflective surface of the reflective layer comprises depositing at 704b a fluid solution that includes the filler layer onto the reflective surface of the reflective layer. One example of depositing at 704b a solution that includes the filler layer is depositing a sol gel solution onto the reflective surface. As described above, the filler layer may include any materials. In some embodiments, depositing at 704 the filler layer comprises depositing a fluid solution that includes a precursor of titanium dioxide (TiO₂), titanium oxide (TiO), titanium butoxide (Ti(OBu)₄), a conductive polymer, zinc oxide (ZnO), doped zinc oxide (AZO), TiOₓ, and/or the like. In addition to the precursor, the fluid solution may include any solvent, such as, but not limited to, water (H2O), hydrogen chloride (HCl), hydrochloric acid, and/or the like. The filler layer may be cured using any method, process, and/or means, such as, but not limited to, using evaporation, heating, baking, and/or the like. For example, in some embodiments, the filler layer is baked after being deposited to remove any remaining organic components. In some embodiments, the method 700 includes heating the filler layer after the filler layer has been deposited at 704, for example to crystallize one or more materials of the filler layer.

The filler layer may be deposited at 704 onto the reflective surface of the reflective layer by depositing the filler layer directly onto the reflective surface of the reflective layer such that the filler layer abuts the reflective surface. Alternatively, when the back electrode of the semiconductor device includes a conductive light transmissive layer (e.g., the conductive light transmissive layer 154 shown in FIG. 3) that is disposed above the reflective surface of the reflective layer, depositing at 704 the filler layer onto the reflective surface may include depositing the filler layer directly onto the conductive light transmissive layer of the back electrode such that the filler layer abuts the conductive light transmissive layer.

As described above, the filler layer is deposited at 704 onto the reflective surface of the reflective layer such that the filler layer at least partially fills at least some of the valleys of the reflective surface. In some embodiments, the filler layer is deposited at 704c such that the filler layer only partially fills the valleys of the reflective surface and leaves at least some of the peaks exposed through the filler layer. In other words, depositing at 704c includes depositing the filler layer such that the filler layer includes filler bodies (e.g., the filler bodies 56 shown in FIGS. 4 and 5) that extend within corresponding valleys of the reflective surface, wherein the filler bodies only partially fill the valleys such that the peaks of the reflective surface are exposed above the filler bodies. In some embodiments, depositing at 704 the filler layer includes depositing at 704d the filler layer such that the filler layer covers at least some of the peaks of the reflective surface. As described above, the depositing at 704 the filler layer may include increasing the effective smoothness of the reflective surface of the reflective layer. Moreover, in some embodiments, depositing at 704 the filler layer may include increasing an amount of the at least one wavelength of light that is scattered by the back electrode, as is also described above.

At 706, the method 700 may include depositing the one or more active semiconductor layers (e.g., the semiconductor layers 36, 38, and/or 40 shown in FIGS. 2 and 4) onto the filler layer such that the filler layer and the back electrode are disposed between the substrate and the active semiconductor layers. In some embodiments, depositing the one or more active semiconductor layers onto the filler layer includes depositing an active semiconductor layer such that the active semiconductor layer abuts the peaks of the reflective surface and abuts the filler layer between the peaks (e.g., as is shown in FIG. 4 with respect to the semiconductor layer 36, the peaks 30, the reflective surface 26, and the filler layer 52). At 708, the method 700 may include depositing one or more additional layers (e.g., the light transmissive electrode 44, adhesive layer 46, and/or cover layer 48 shown in FIGS. 2 and 4) above the one or more active semiconductor layers to form a photovoltaic device.

### Example

The following provides one example of the method 700 shown in FIG. 11 and a sample semiconductor device (e.g., the semiconductor device 10 shown in FIGS. 1, 2, 4, and 5) manufactured according to the method 700. A sample filler layer was prepared using a sol gel solution of 4 wt % Ti(OBu)₄, with a 2:1 molar ratio of H₂O:Ti(OBu)₄, and a 0.04:1 molar ratio of HCl:Ti(OBu)₄. A substrate and back electrode of the sample semiconductor device was provided by sputtering a reflective layer of Ag on a ZnO substrate. The ZnO substrate was manufactured using low pressure chemical vapor deposition (LPCVD). The sample filler layer was deposited onto the reflective layer by spin casting the sol gel solution directly onto the reflective layer of Ag. The sol gel solution was spin cast at approximately 1000 rpm. For mass production, other coating methods (such as, but not limited to, doctor blading and/or the like) may be used in addition or as an alternative to spin casting.

After spin casting, the deposited sol gel solution was baked in an oven at approximately 250° C. for approximately 1 hour to remove organic components. For device measurements, single junction NIP solar cells were made with an active semiconductor layer of approximately 1.5 microns of microcrystalline Si deposited by plasma enhanced chemical vapor deposition (PECVD). The results described and/or illustrated herein may also apply for amorphous and tandem cells. Indium tin oxide (ITO) was sputtered on the active semiconductor layer of microcrystalline Si to make a light transmissive electrode of the sample semiconductor device.

A control semiconductor device was manufactured by providing a ZnO substrate and sputtering a reflective layer of Ag on the ZnO substrate. The ZnO substrate was manufactured using LPCVD. An active semiconductor layer of approximately 1.5 microns of microcrystalline Si was deposited onto the reflective layer by PECVD to form a single junction NIP control semiconductor device. The control semiconductor device does not include any filler layer disposed between the reflective layer and the active semiconductor layer.

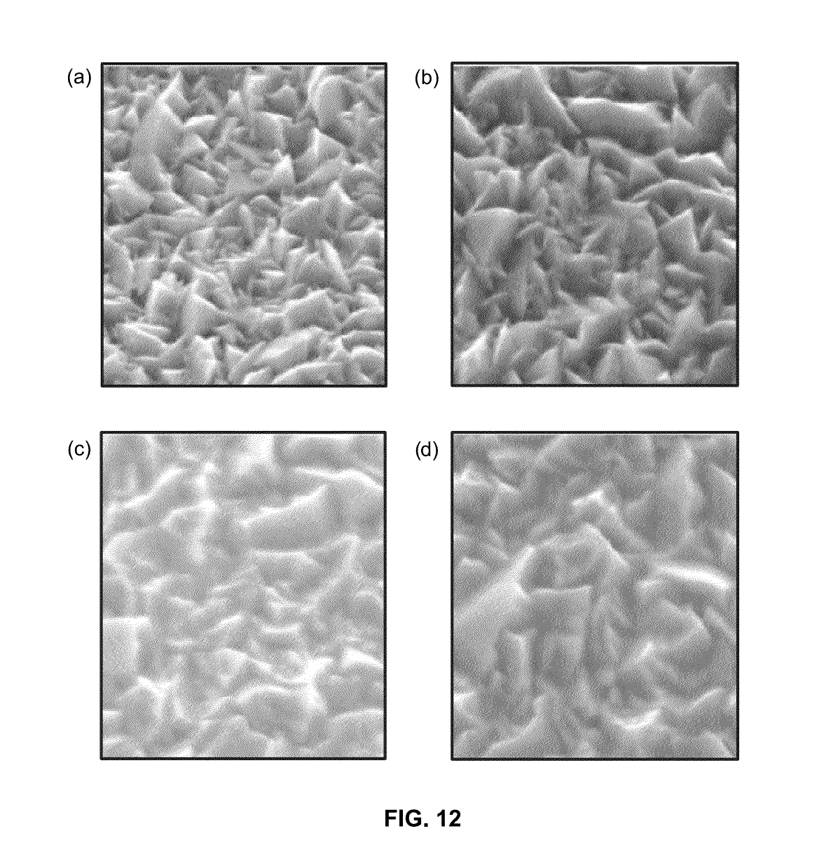

FIG. 12 illustrates the back electrode of the sample semiconductor device and the control semiconductor device at various magnifications. Specifically, FIG. 12a illustrates the control semiconductor device at approximately 20,000 times magnification, FIG. 12b illustrates the control semiconductor device at approximately 30,000 times magnification, FIG. 12c illustrates the sample semiconductor device at approximately 20,000 times magnification, and FIG. 12c illustrates the sample semiconductor device at approximately 30,000 times magnification.

Open current voltage (V_{oc}) and fill factor increased in the sample semiconductor device having the sample filler layer as compared to the control semiconductor device. For example, the V_{oc} increased from approximately 409 mV for the control semiconductor device to approximately 422 mV for sample semiconductor device having the sample filler layer. Similarly, the fill factor increased from approximately 56.6% for the control semiconductor device to approximately 60.4% for the sample semiconductor device having the sample filler layer. The unexpected increases in V_{oc} and fill factor may result from the filler layer effectively smoothing out the reflective surface of the reflective layer by at least partially filling in the valleys, for example as is described above with respect to the filler layer 52 shown in FIGS. 2, 4, and 5. Such effective smoothing out can be seen by comparing FIGS. 12a and 12b with FIGS. 12c and 12d. For example, the rounded valleys of the sample semiconductor device having the sample filler layer replace the relatively sharp valleys present in the control semiconductor device that does not include the sample filler layer. The rounded valleys of the sample semiconductor device may result in fewer defects in the active semiconductor layer that is deposited (e.g., using PECVD) onto the reflective layer of the sample semiconductor device. Such fewer defects may lead to a relatively low V, and/or relatively low fill factor. In this example, an AM 1.5 solar simulator was used to determine V_{oc} and fill factor.

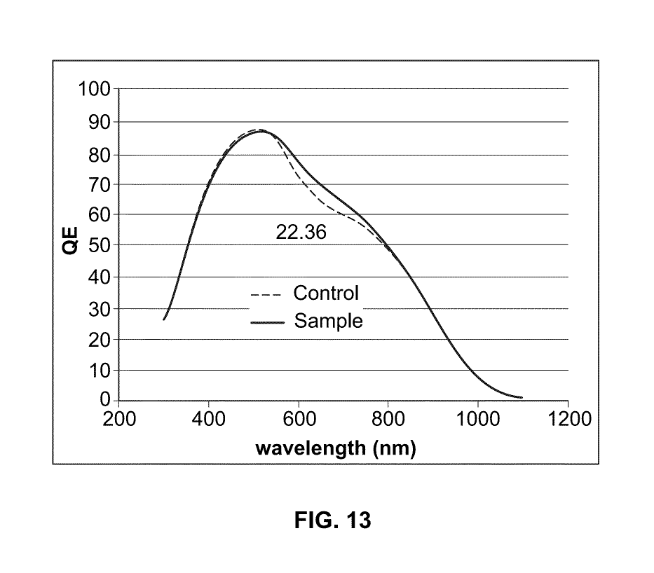

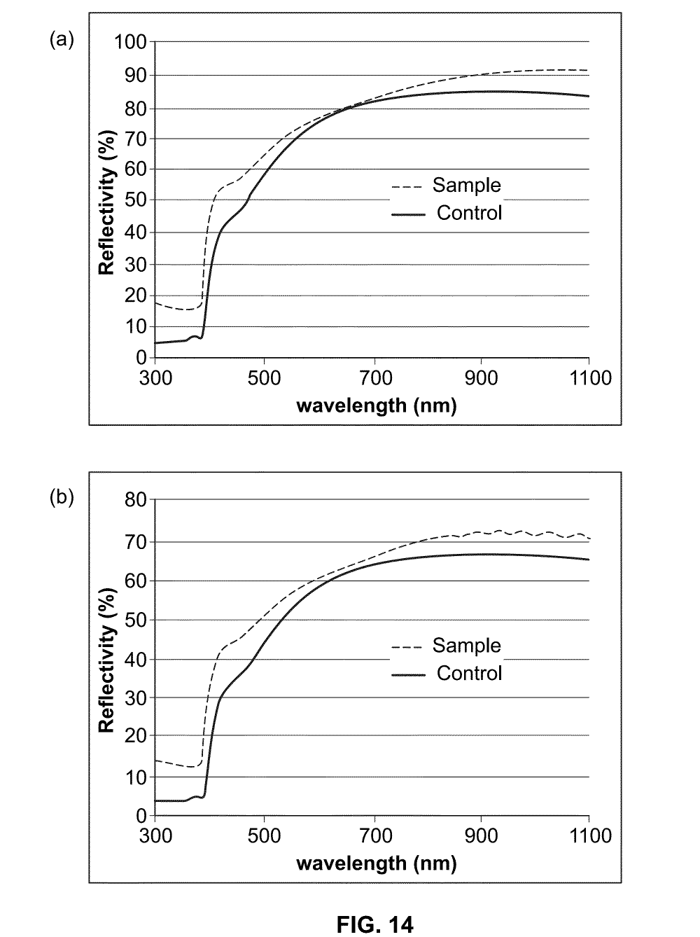

When other techniques (instead of the filler layer described and/or illustrated herein), such as reactive ion etching (RIE), are used to smooth LPCVD ZnO surfaces, short current density (J_{sc}) may decrease, for example due to an increase in specular reflection and/or a corresponding decrease in the amount of light diffracted at larger angles. But, in the case of single junction microcrystalline semiconductor devices, a significant increase in the J_{sc} of the sample semiconductor device having the sample filler layer was seen as compared to the control semiconductor device that does not include the sample filler layer. Specifically, FIG. 13 illustrates a graph of EQE plots for the sample semiconductor device and the control semiconductor device. As can be seen in FIG. 13, the J_{sc} increased from approximately 22.2 mA/cm² for the control semiconductor device to approximately 22.9 mA/cm² for the sample semiconductor device. The EQE plot shown in FIG. 13 illustrates that the increase in current occurs from approximately 550 nm to approximately 800 nm. It appears that a portion of the light in such a range is reflected off the filler layer and so is not at risk of being absorbed by the substrate or being absorbed by surface plasmons at the interface between the substrate and the reflective layer. FIG. 14 is a graph illustrating reflectivity data for the sample semiconductor device and for the control semiconductor device. Reflectivity data shown in FIGS. 14a and 14b confirms that less light is being absorbed by the back electrode (i.e. the reflective layer) when the filler layer is present. In this example, an EQE set up was used to determine J_{sc}.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the subject matter set forth herein without departing from its scope. Dimensions, types of materials, orientations of the various components, and the number and positions of the various components described herein are intended to define parameters of certain embodiments, and are by no means limiting and are merely example embodiments. Many other embodiments and modifications within the spirit and scope of the claims will be apparent to one of ordinary skill in the art upon reviewing the above description. The scope of the inventive subject matter described herein should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

What is claimed is:

1. A method for manufacturing a semiconductor device, the method comprising:
providing a substrate and a back electrode disposed between the substrate and an active semiconductor layer, the back electrode having a reflective layer that is reflective to at least one wavelength of light, the reflective layer comprising an undulating reflective surface having an undulating profile that includes peaks that protrude away from the substrate and valleys that extend into the reflective layer toward the substrate;
depositing a filler layer onto the reflective layer of the back electrode such that the active semiconductor layer can be subsequently deposited onto the filler layer, the filler layer at least partially filling one or more of the valleys of the undulating profile of the reflective surface, the filler layer being transmissive to the at least one wavelength of light such that the at least one wavelength of light can pass through the filler layer to the reflective layer of the back electrode; and
depositing the active semiconductor layer onto the filler layer such that the filler layer and the back electrode are disposed between the substrate and the active semiconductor layer, wherein the filler layer is positioned such that at least a portion of incident light passes through the active semiconductor layer into the filler layer, passes through the filler layer, is reflected by the reflective layer of the back electrode, and passes back through the filler layer to be absorbed by the active semiconductor layer.

2. The method of claim 1, wherein depositing the filler layer onto the reflective layer of the back electrode comprises depositing the filler layer such that the filler layer only partially fills the valleys of the reflective surface and leaves at least some of the peaks exposed through the filler layer.

3. The method of claim 1, wherein depositing the filler layer onto the reflective layer of the back electrode comprises depositing the filler layer such that the filler layer includes filler bodies that extend within corresponding valleys of the reflective surface, the filler bodies only partially filling the valleys such that the peaks of the reflective surface are exposed above the filler bodies.

4. The method of claim 1, wherein depositing the filler layer onto the reflective layer of the back electrode comprises depositing the filler layer such that the filler layer covers at least some of the peaks of the reflective surface.

5. The method of claim 1, wherein depositing the filler layer onto the reflective layer of the back electrode comprises depositing a fluid solution that includes the filler layer onto the reflective surface of the reflective layer.

6. The method of claim 1, wherein depositing the filler layer onto the reflective layer of the back electrode comprises depositing a sol gel solution onto the reflective surface of the reflective layer.

7. The method of claim 1, wherein depositing the filler layer onto the reflective layer of the back electrode comprises depositing a fluid solution that includes at least one of titanium dioxide (TiO₂), titanium oxide (TiO), titanium butoxide (Ti(OBu)₄), a conductive polymer, zinc oxide (ZnO), TiOₓ, or doped zinc oxide (AZO).

8. The method of claim 1, wherein depositing the filler layer onto the reflective layer of the back electrode comprises depositing the filler layer using spin coating.

9. The method of claim 1, wherein depositing the filler layer onto the reflective layer of the back electrode comprises increasing an effective smoothness of the reflective surface of the reflective layer.

10. The method of claim 1, wherein depositing the filler layer onto the reflective layer of the back electrode comprises increasing an amount of the at least one wavelength of light that is scattered by the back electrode.

11. The method of claim 1, wherein depositing the filler layer onto the reflective layer of the back electrode comprises one of:
depositing the filler layer directly onto the reflective surface of the reflective layer such that the filler layer abuts the reflective surface; or
depositing the filler layer directly onto a conductive light transmissive layer of the back electrode that is disposed above the reflective surface of the reflective layer such that the filler layer abuts the conductive light transmissive layer.

12. The method of claim 1, wherein depositing the filler layer onto the reflective layer of the back electrode comprises depositing the filler layer onto at least one of a metal or a metal alloy.

13. The method of claim 1, wherein depositing the active semiconductor layer onto the filler layer comprises depositing the active semiconductor layer such that the active semiconductor layer abuts the peaks of the reflective surface and abuts the filler layer between the peaks.

14. The method of claim 1, further comprising depositing one or more additional layers above the active semiconductor layer to form a photovoltaic device.

15. The method of claim 1, wherein the filler layer is formed from different materials than the back electrode.

16. A semiconductor device comprising:
a substrate;
an active semiconductor layer;
a back electrode disposed between the substrate and the active semiconductor layer, the back electrode comprising a reflective layer that is configured to reflect at least one wavelength of light, the reflective layer comprising a reflective surface having an undulating profile that includes peaks that protrude away from the substrate and valleys that extend into the reflective layer toward the substrate; and
a filler layer disposed between the reflective surface of the reflective layer of the back electrode and the active semiconductor layer, the filler layer at least partially filling one or more of the valleys of the undulating profile of the reflective surface, the filler layer being transmissive to the at least one wavelength of light such that the at least one wavelength of light can pass through the filler layer to the reflective layer of the back electrode, wherein the filler layer is positioned such that at least a portion of incident light passes through the active semiconductor layer into the filler layer, passes through the filler layer, is reflected by the reflective layer of the back electrode, and passes back through the filler layer to be absorbed by the active semiconductor layer.

17. The semiconductor device of claim 16, wherein the filler layer is a solution-based filler layer.

18. The semiconductor device of claim 16, wherein at least some of the peaks of the reflective surface of the reflective layer are exposed through the filler layer.

19. The semiconductor device of claim 16, wherein the filler layer includes filler bodies that extend within corresponding valleys of the reflective surface of the reflective layer, the filler bodies only partially filling the valleys such that the peaks of the reflective surface are exposed above the filler bodies.

20. The semiconductor device of claim 16, wherein the filler layer is a non-continuous layer having separate and discrete filler bodies that are separated from each other by the peaks of the reflective surface.

21. The semiconductor device of claim 16, wherein the filler layer covers at least some of the peaks of the reflective surface of the reflective layer.

22. The semiconductor device of claim 16, wherein the filler layer comprises at least one of titanium dioxide (TiO₂), titanium oxide (TiO), titanium butoxide (Ti(OBu)₄), a conductive polymer, zinc oxide (ZnO), TiOₓ, or doped zinc oxide (AZO).

23. The semiconductor device of claim 16, wherein the filler layer increases an effective smoothness of the reflective surface of the reflective layer.

24. The semiconductor device of claim 16, wherein the filler layer increases an amount of the at least one wavelength of light that is scattered by the back electrode.

25. The semiconductor device of claim 16, wherein the back electrode includes a conductive light transmissive layer disposed directly on the reflective surface of the reflective layer such that the conductive light transmissive layer abuts the reflective surface, the filler layer being disposed directly on the conductive light transmissive layer such that the filler layer abuts the conductive light transmissive layer.

26. The semiconductor device of claim 16, wherein the reflective layer of the back electrode comprises at least one of a metal or a metal alloy.

27. The semiconductor device of claim 16, further comprising a light transmissive electrode disposed above the active semiconductor layer.

28. A method for manufacturing a semiconductor device, the method comprising:
providing a substrate and a back electrode disposed between the substrate and an active semiconductor layer, the back electrode having a reflective layer that is reflective to at least one wavelength of light, the reflective layer comprising an undulating reflective surface having an undulating profile that includes peaks that protrude away from the substrate and valleys that extend into the reflective layer toward the substrate, the back electrode comprising a conductive light transmissive layer that is disposed above the reflective surface of the reflective layer such that the reflective layer is disposed between the substrate and the conductive light transmissive layer;
depositing a filler layer onto the conductive light transmissive layer of the back electrode such that the active semiconductor layer can be subsequently deposited onto the filler layer, the filler layer at least partially filling one or more of the valleys of the undulating profile of the reflective surface, the filler layer being transmissive to the at least one wavelength of light such that the at least one wavelength of light can pass through the filler layer to the reflective layer of the back electrode; and
depositing the active semiconductor layer onto the filler layer such that the filler layer and the back electrode are disposed between the substrate and the active semiconductor layer, wherein the filler layer is positioned such that at least a portion of incident light passes through the active semiconductor layer into the filler layer, passes through the filler layer into the conductive light transmissive layer, passes through the conductive light transmissive layer, is reflected by the reflective layer of the back electrode, and passes back through the conductive light transmissive layer and the filler layer to be absorbed by the active semiconductor layer.
